(19) United States
(12) Patent Application Publication
(10) Pub. No.: US 2010/0185914 A1
(43) Pub. Date: Jul. 22, 2010

(54) Systems and Methods for Reduced Complexity Data Processing

(76) Inventors: Weijun Tan, Longmont, CO (US); Hao Zhong, San Jose, CA (US)

Correspondence Address: Hamilton,DeSanctis & Cha (LSI), 8601 W. CROSS DRIVE, F5-301, LITTLETON, CO, 80123, US

(21) Appl. No.: 12/527,241

(22) PCT Filed: Sep. 28, 2007
(86) PCT No.: PCT/US07/79949

§ 371 Date: Aug. 14, 2009

(51) Int. Cl. H03M 13/27; G06F 11/10; H03M 13/05

(52) U.S. Cl. 714/752; 714/E11.032

(57) ABSTRACT

Various embodiments of the present invention provide systems and methods for processing information. For example, a decoding system is disclosed that includes a de-interleaver. The de-interleaver is operable to receive an interleaved codeword that includes two or more reduced codewords interleaved together. Further, the de-interleaver is operable to provide a representation of the two or more reduced codewords. The systems also include a decoder that is operable to decode the two or more reduced codewords. In some instances of the aforementioned embodiments, the decoder is an LDPC decoder that is tailored to the size of one or both of the two or more reduced codewords.

### BACKGROUND OF THE INVENTION

The present invention is related to systems and methods for processing information, and more particularly to systems and methods for encoding and/or decoding data.

A number of systems rely on encoding information before a transfer of the information, followed by a decoding process to recover the transferred information. As an example, the transfer of information to and from a magnetic storage medium typically involves an encoding process that precedes the storage of the information and a decoding process that follows an access to the magnetic storage medium. As another example, various wireless transmission systems include an encode process applied before information is wirelessly transferred followed by a decode process applied to the received information.

FIG. 1 shows a block diagram of an exemplary data transfer system 100 including an encode stage 110, a decode stage 150 and a transfer stage 170. Encode stage 110 includes a Low Density Parity Check (LDPC) encoder 115, an interleaver 125, and a recording channel/transmitter 135. Decoder stage 150 includes a detector 155 that may be, for example, either a maximum a posteriori algorithm detector or a soft output Viterbi algorithm. In addition, decoder stage 150 includes a de-interleaver 160 and an interleaver 157, and an LDPC decoder 165. In operation, a data input 103 is provided to LDPC encoder 115 that operates to encode the data using LDPC encoding techniques, and the encoded information is interleaved using interleaver 125. The encoded and interleaved information is received by recording channel/transmitter 135 that operates to transfer the received information via data transfer medium 170. Detector 155 receives and identifies the information from data transfer medium 170. The identified information is de-interleaved by de-interleaver 160, and decoded using LDPC decoder 165. The process of decoding is iterative with the data from LDPC decoder 165 being returned for additional processing via interleaver 157. Once the decoding process is completed, the decoded information is provided as a data output 105.

Where, for example, data transfer system 100 is used to provide information to and from a magnetic storage medium, the code length of the LDPC code used by encoder 115 is generally equivalent to the sector size of the magnetic storage medium to ensure high error correction capability. Such long code lengths result in complex implementations of decoder stage 150. While such complex implementations may provide effective error correction capability, they are often not commercially viable.

Hence, for at least the aforementioned reasons, there exists a need in the art for advanced systems and methods for processing information.

### BRIEF SUMMARY OF THE INVENTION

The present invention is related to systems and methods for processing information, and more particularly to systems and methods for encoding and/or decoding data.

Various embodiments of the present invention provide decoding systems that include a de-interleaver. The de-interleaver is operable to receive an interleaved codeword that includes two or more reduced codewords interleaved together. Further, the de-interleaver is operable to provide a representation of the two or more reduced codewords. In some cases, the two or more reduced codewords are interleaved by random, pseudo-random, or block interleaver. The systems also include a decoder based on reduced-size parity check matrix that is operable to decode the two or more reduced codewords. In some instances of the aforementioned embodiments, the decoder is an LDPC decoder that is tailored to the size of one of the two or more reduced codeword matrices.

In various instances of the aforementioned embodiments, each of the reduced codeword matrices includes a number of columns that each correspond to respective columns of the interleaved codeword matrix. In such cases, the column weight of each of the columns in the reduced codeword matrices is the same as that of the corresponding column in the interleaved codeword matrix. In various embodiments of the present invention, the total number of the two or more codeword matrices a power of two (e.g., 2, 4, 8, 16 . . . ). In other instances of the present invention, the total number of the codewords that are interleaved is a value other than a power of two.

Other embodiments of the present invention provide data transfer systems. Such data transfer systems include an encoder that is operable to receive an input data set and to provide an encoded data set. The encoded data set is represented as two or more reduced codewords. The systems further include an interleaver that is operable to interleave the two or more reduced codeword. For instance, where two codewords re interleaved to create a single interleaved codeword, the reduced codeword have corresponding reduced parity matrices, while the interleaved codeword has a larger overall parity matrix.

Yet other embodiments of the present invention provide methods for reduced complexity processing. The methods include receiving an interleaved codeword that is generated by interleaving two or more reduced codewords. The interleaved codeword includes a first number of columns, and each of the two or more reduced codeword matrices includes a second number of columns. The second number of columns is less than the first number of columns, and the column weight of each column of the two or more reduced codeword matrices is the same as the column weight of respective, corresponding columns of the interleaved codeword matrix. The methods further include de-interleaving the interleaved codeword matrix to yield the two or more reduced codeword matrices, and performing LDPC decoding on each of the two or more reduced codeword matrices. In some cases, the aforementioned methods further include receiving a data set, encoding the data set to yield the two or more reduced codeword matrices, and interleaving the two or more reduced codeword matrices to create the interleaved codeword matrix.

This summary provides only a general outline of some embodiments of the invention. Many other objects, features, advantages and other embodiments of the invention will become more fully apparent from the following detailed description, the appended claims and the accompanying drawings.

### BRIEF DESCRIPTION OF THE DRAWINGS

A further understanding of the various embodiments of the present invention may be realized by reference to the figures which are described in remaining portions of the specification. In the figures, like reference numerals are used throughout several drawings to refer to similar components. In some instances, a sub-label consisting of a lower case letter is associated with a reference numeral to denote one of multiple similar components. When reference is made to a reference numeral without specification to an existing sub-label, it is intended to refer to all such multiple similar components.

FIG. 1 is a prior art data transfer system;

FIG. 2 is a flow diagram showing a relationship between a desired codeword and reduced codewords, and a process of producing reduced codewords and interleaving the reduced codewords in accordance with one or more embodiments of the present invention;

FIGS. 3a-3d show exemplary relationships between a desired codeword, two “half” size reduced codewords, and an interleaved codeword that may be used in relation to various embodiments of the present invention;

FIGS. 4a-4d show exemplary relationships between a desired codeword, four “quarter” size reduced codewords, and an interleaved codeword that may be used in relation to various embodiments of the present invention;

FIG. 5 is a data transfer system utilizing reduced codewords and interleaved codewords in accordance with some embodiments of the present invention; and

FIG. 6 is a flow diagram depicting a process in accordance with one or more embodiments of the present invention for data processing using reduced codewords.

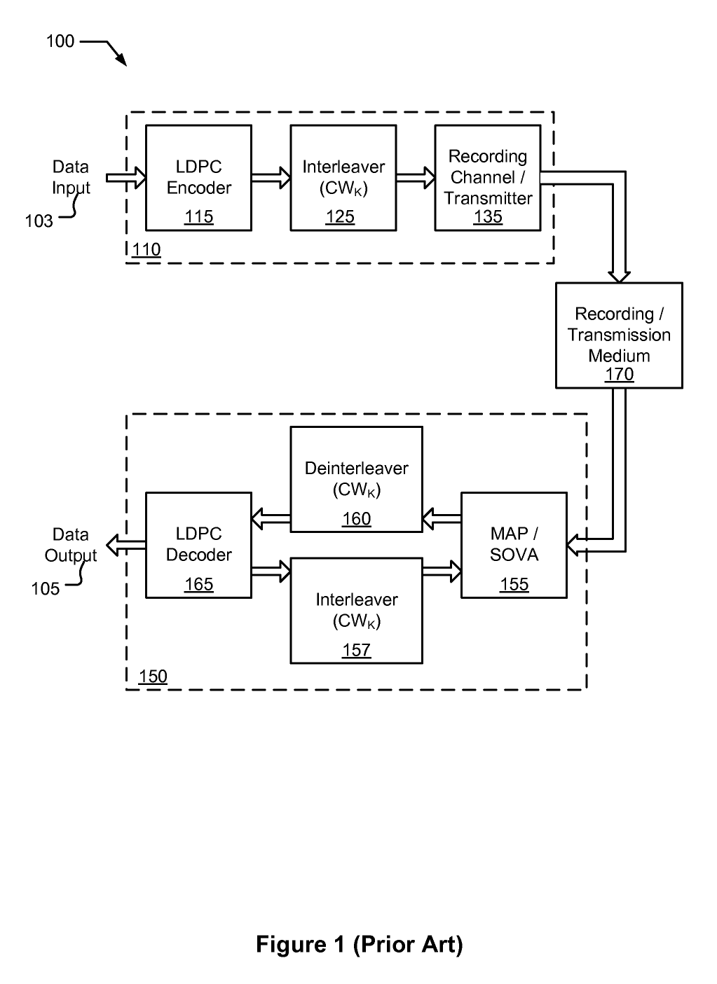

### DETAILED DESCRIPTION OF THE INVENTION

The present invention is related to systems and methods for processing information, and more particularly to systems and methods for encoding and/or decoding data.

Various embodiments of the present invention provide data processing systems that include a de-interleaver. As used herein, the term “de-interleaver” without further definition is used in its broadest sense to mean any circuit, system, algorithm or process that operates to undo a corresponding interleaving process. As used herein, the term “interleaver” is used in its broadest sense to mean any circuit, system, algorithm or process that causes one data set to be shuffled so that it becomes a shuffled version of the original data set, or causes one data set to be intermixed with another data set. Thus, as just one example, an interleaver may take a codeword of data and shuffle the individual elements of the codeword with another codeword to create an interleaved codeword. Based on the disclosure provided herein, one of ordinary skill in the art will recognize a variety of interleavers and de-interleavers that may be used in relation to various embodiments of the present invention.

The de-interleaver is operable to receive an interleaved codeword that includes two or more reduced codewords that have been interleaved together. Further, the de-interleaver is operable to provide a representation of the two or more reduced codewords. As used herein, the phrase “interleaved codeword” is used in its broadest sense to mean any set of data that was created by combining two or more smaller sets of data. Further, as used herein, the phrase “reduced codeword” is used in its broadest sense to mean any set of data including both original data and redundancy data that is smaller than another set of data that is intended to represent either in whole or in part. The systems also include a decoder that is operable to decode the two or more reduced codewords. In some instances of the aforementioned embodiments, the decoder is an LDPC decoder that is tailored to the size of one of the two or more reduced codeword matrices. In such instances, the complexity of the LDPC decoder may be greatly reduced where it is tailored to decode a codeword of the size of the reduced codewords. This reduction in complexity of the decoder may be achieved without a substantial impact on the error correction performance of the LDPC resulting from a reduction in the codeword size due at least in part to the novel approach of interleaving and de-interleaving.

As one of many advantages, some embodiments of the present invention are capable of performing well in comparison with comparable SOVA/ISP, SOVA/TPC, SOVASP/SP and SOVASP/TPC, SOVAsp/LDPCsp, SOVA/MAP/LDPC and MAP/SOVA/turboCode architectures, and in some cases better than one or more of the aforementioned architectures. Further, such performance may be achieved using less complex circuitry and/or using less die area where a system in accordance with the present invention is implemented as part of a semiconductor device.

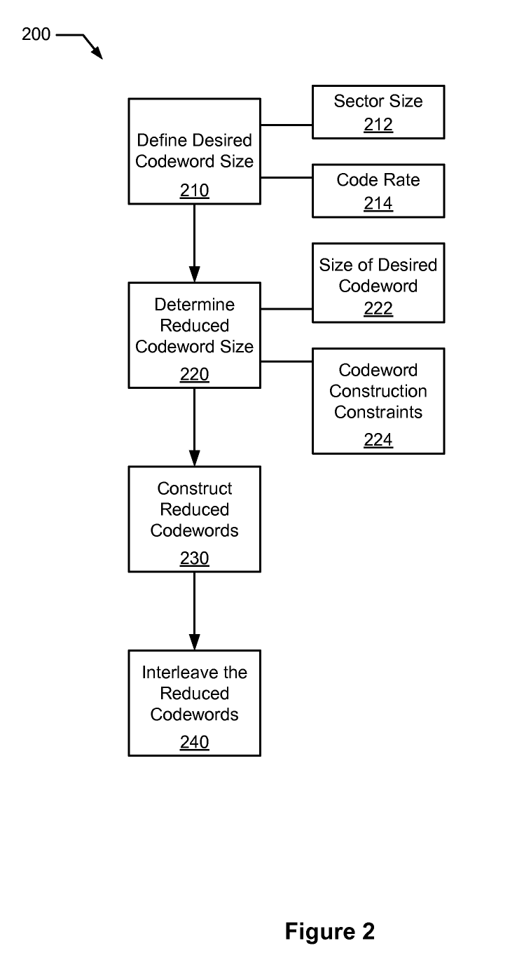

Turning to FIG. 2, a flow diagram 200 depicts a method in accordance with one or more embodiments of the present invention for producing reduced and interleaved codewords based on a desired codeword size. Following flow diagram 200, a desired codeword size is defined (block 210). Such a desired codeword may be of a size and structure that is conducive to achieving a desired result, but which may demand a relatively complex encoder and/or decoder design to utilize. In one particular instance where the codeword is used to process data that is to be stored to and retrieved from a storage medium, the codeword may be design in a way that considers the sector size of the storage medium 212 and the desired code rate 214 as is known in the art.

A desired codeword corresponds to a desired codeword matrix that includes a number (M) of rows and a number (N) of columns. The number of columns defines the codeword length, and the number of rows represent the number of parity check equations used for the codeword. Each column of the desired codeword matrix includes a number of logic ‘1’s and a number of logic ‘0’s, and the number of logic ‘1’s is generally referred to as a column weight (Wc). Similarly, each row of desired codeword matrix 405 includes a number of logic ‘1’s and a number of logic ‘0’s, and the number of logic ‘1’s is generally referred to as a row weight (Wr).

As an example, a parity check matrix of the desired codeword matrix may be written as:

$$H = [ \begin{matrix}{H}_{1 , 1} & {H}_{1 , 2} & … & {H}_{1 , N} \\ {H}_{2 , 1} & {H}_{2 , 2} & … & {H}_{2 , N} \\ … & … & ⋱ & … \\ {H}_{M , 1} & {H}_{M , 2} & … & {H}_{M , N}\end{matrix} ]$$

where each sub-matrix Hi, j is a p×p circulant over GF(2). It should be noted that a zero matrix is a special case of circulants where the weight is zero. In some embodiments of the present invention, the parity check matrix incorporated by desired codeword matrix corresponds to a randomly constructed high-rate regular QC-LDPC code, where all the nonzero circulants may have different weights. Further, the parity check matrix may be constructed such that there are no cycles of degree four. In some cases, it may be desirable to construct a parity check matrix with minimum column weight as such may reduce the complexity of any implemented LDPC decoder. Details of specific code implementations that may be used in accordance with one or more embodiments of the present invention are discussed in Zhong et al., “Quasi-Cyclic LDPC Codes for the Magnetic Recording Channel: Code Design and VLSI Implementation”, IEEE Transactions on Magnetics, Vol. 43, No. 3, March 2007. The entirety of the aforementioned reference is incorporated herein by reference for all purposes. Further, it should be noted that a variety of code construction techniques and parameters are well known in the art, and that based on the disclosure provided herein, one of ordinary skill in the art would recognize other codes and/or code construction techniques and parameters that may be used in relation to different embodiments of the present invention.

Based on the desired codeword (block 210), a size of a reduced codeword is defined (block 220). The size of the reduced codeword may be determined based on a desired codeword size 222 and various codeword construction constraints 224 as are known in the art. In some cases, the desired codeword size is chosen based on a desired level of encoder and decoder complexity and/or size. In some embodiments of the present invention, the reduced codeword corresponds to the reduced codeword matrix that is the number of columns (N) and the number of rows (M) of the desired codeword matrix divided by a power of two. The following equation describes the dimensions of such a reduced codeword:

H=(N/2ⁿ)×(M/2ⁿ),

where n is an integer greater than zero. In other cases, the size is the desired codeword matrix divided by an integer value other than a power of two.

Once the size of the reduced codeword is defined (block 220), reduced codewords are created based on the determined size and the desired codeword size (block 230). This includes defining 2ⁿ reduced matrices that each represent a subset of the rows and columns of the desired codeword matrix. Thus, for example, where n equals one, two reduced matrices are defined with the first of the two matrices representing rows 0 through (M/2)−1 of columns 0 through (N/2)−1 of the desired codeword matrix. The second of the two reduced codeword matrices represents rows M/2 through M of columns N/2 through N of the desired codeword matrix. The column weight of each column of the reduced codeword matrices is the same as the column weight for the corresponding column of the desired codeword matrix. Thus, whatever logic ‘1’s are distributed across rows 0 through (M/2)−1 of columns 0 through (N/2)−1 are incorporated into one of the two reduced codeword matrices, and whatever logic ‘1’s are distributed across rows M/2 through M of columns N/2 through N are incorporated into the other of the two reduced codeword matrices. Reduced codewords corresponding to the aforementioned reduced codeword matrices allow for simpler decoder designs, while maintaining very good performance when compared with processing using the desired codeword.

In some cases, the aforementioned reduced codewords may be interleaved to create an interleaved codeword (block 240). The interleaved codeword corresponds approximately to the above mentioned desired codeword matrix, and offers a performance better than processing the individual reduced codewords. It should be noted that one or more of the processes discussed in relation to flow diagram 200 may be performed automatically using a microprocessor based machine executing software instructions that cause the processes to execute. Such software instructions may be maintained on a computer readable medium accessible to the microprocessor based machine. Such a microprocessor based machine may be, but is not limited to, a personal computer. For example, software instructions executable by a microprocessor based device may be designed to construct the reduced codewords (block 230) and to interleave the reduced codewords (block 240). Based on the disclosure provided herein, one of ordinary skill in the art will recognize a variety of software programs that may be developed to perform the functions of one or more of the processes of flow diagram 200.

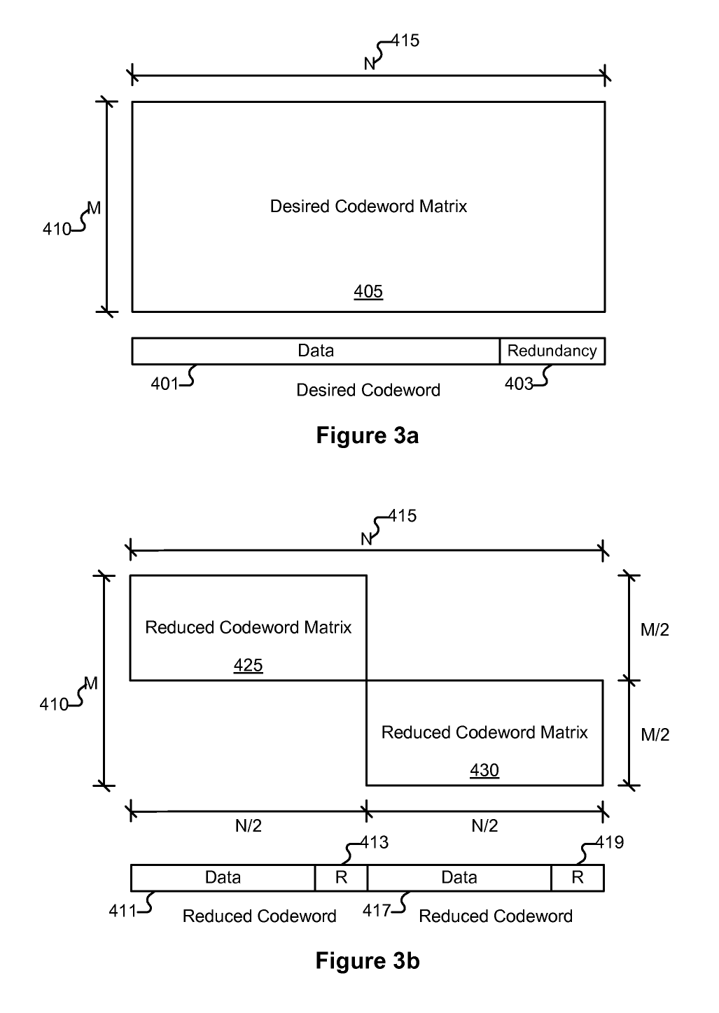

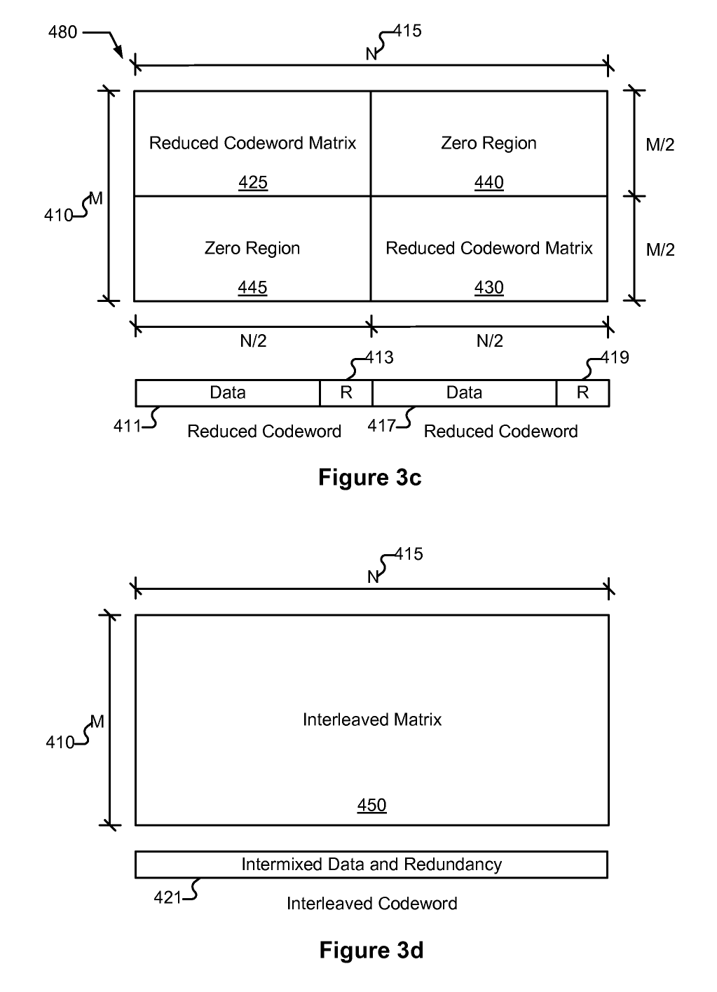

Turning to FIG. 3, an example of generating reduced codewords, and an interleaved codeword corresponding to desired codeword matrix where n equals one is shown. Turning to FIG. 3a, a standard LDPC codeword including data 401 and redundancy 403 is represented as desired codeword matrix 405. Desired codeword matrix 405 is comprised of a number (M) of rows 410 and a number (N) of columns 415. The number of columns 415 defines the LDPC code length, and the number of rows 410 represent the number of parity check equations used in the LDPC code. Each column of desired codeword matrix 405 includes a number of logic ‘1’s and a number of logic ‘0’s, and the number of logic ‘1’s is generally referred to as a column weight (Wc). Similarly, each row of desired codeword matrix 405 includes a number of logic ‘1’s and a number of logic ‘0’s, and the number of logic ‘1’s is generally referred to as a row weight (Wr).

Turning to FIG. 3b, two reduced codewords are designed to be one half the size (i.e., n=1) of the above mentioned standard codeword. The first reduced codeword includes data 411 and redundancy 413, and the second reduced codeword includes data 417 and redundancy 419. The first reduced codeword is represented by a reduced codeword matrix 425, and the second reduced codeword is represented by a reduced codeword matrix 430. In this case, each of reduced codeword matrices 425, 430 includes half of the rows (M/2) and half the columns (N/2) of that included in desired codeword matrix 405. Reduced codeword matrix 425 is derived from the columns 0 through (N/2)−1 and the rows 0 through (M/2)−1 of desired codeword matrix 405. Reduced codeword matrix 430 is derived from columns N/2 through N and rows M/2 through M of desired codeword matrix 405.

The column weight of each of columns 0 through (N/2)−1 of reduced codeword matrix 425 is the same as the corresponding columns of desired codeword matrix 405. Thus, whatever logic ‘1’s are distributed across rows 0 through (N/2)−1 and columns 0 through (M/2)−1 are incorporated into reduced codeword matrix 425. Similarly, the column weight of each of columns N/2 through N (column N/2 corresponds to the first column of reduced codeword matrix 430, and column N corresponds to the last column of reduced codeword matrix 430) of reduced codeword matrix 430 is the same as the corresponding columns of desired codeword matrix 405. Thus, whatever logic ‘1’s are distributed across rows N/2 through N and columns M/2 through M are incorporated into reduced codeword matrix 430. With this redistribution complete, all of the logic ‘1’s originally included in desired codeword matrix 405 are incorporated into one or the other of reduced codeword matrix 425 and reduced codeword matrix 430.

As shown in FIG. 3c and FIG. 3d, the two reduced codeword matrices 425, 426 may be used to generate an interleaved codeword matrix 450. In particular, as shown in FIG. 3c, a zero region 440 is assumed for the region comprising rows 0 through (N/2)−1 of columns M/2 through M. Another zero region 445 is assumed comprising rows (N/2) through N of columns 0 through (M/2)−1. By including zero regions 440, 445, an overall matrix 480 is defined that exhibits the same number of columns and rows as included in desired codeword matrix 405. Zero regions 440, 445 may then be interleaved with reduced matrix 425 and reduced matrix 430. This interleaving process may be performed on a column by column basis. Interleaving on a column by column basis may include, but is not limited to, intermixing the corresponding columns of reduced codeword matrix 425 and zero region 445 with the corresponding columns of reduced codeword matrix 430 and zero region 440. A row by row basis may be similarly accomplished by intermixing the corresponding rows of reduced codeword matrix 425 and zero region 440 with the corresponding rows of reduced codeword matrix 430 and zero region 445.

In some embodiments of the present invention, the interleaving is random. However, for purposes of discussion a regular interleaving is described where every other column comes from columns 0 through (N/2)−1 of matrix 480, and the other columns are selected from columns N/2 through N of matrix 480. This interleaving process operates to distribute the logic ‘1’s randomly across an interleaved codeword matrix 450. Using the example of regular interleaving, the first column of interleaved codeword matrix 450 is the zero column of matrix 480, the second column of interleaved codeword matrix 450 is the N/2 column of matrix 480, the third column of interleaved codeword matrix 450 is the one column of matrix 480, and the fourth column of interleaved codeword matrix 450 is the (N/2)+1 column of matrix 480. This process of interleaving is carried out until all columns of matrix 480 have been included in interleaved codeword matrix 450. Again, it should be noted that a random or pseudo-random interleaving pattern may yield a more robust codeword. Based on the disclosure provided herein, one of ordinary skill in the art will recognize a myriad of interleaving schemes and approaches that may be applied to matrix 480 to achieve a desirable interleaved codeword matrix 450. In any event, the aforementioned two reduced codeword matrices are interleaved together to create an interleaved codeword 421. Interleaved codeword 421 includes data 411, 417 and redundancy 417, 419 randomly or pseudo-randomly intermixed.

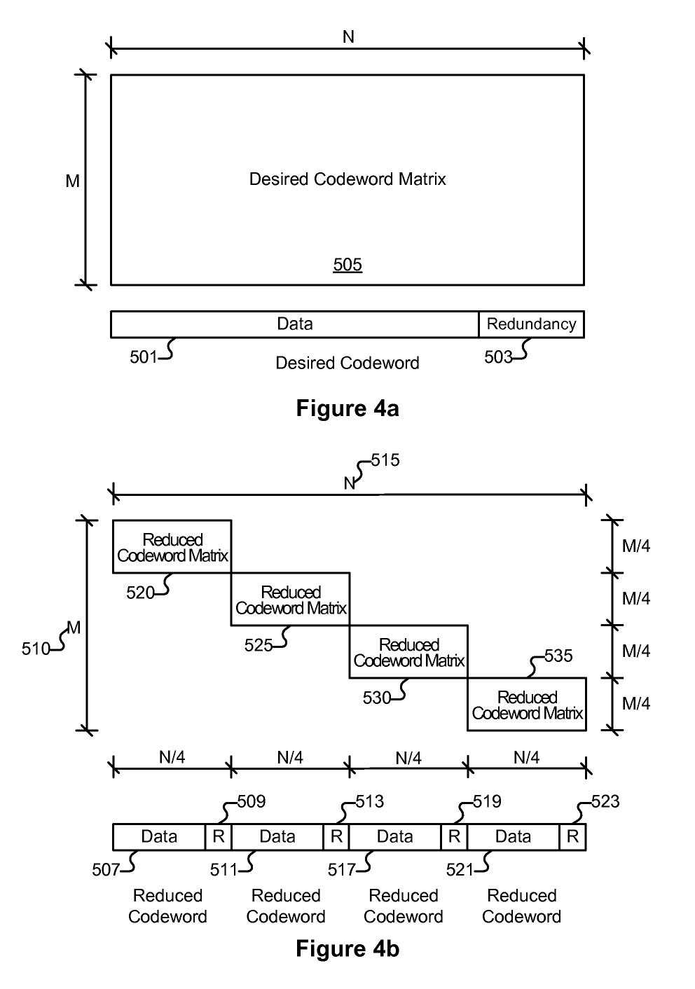

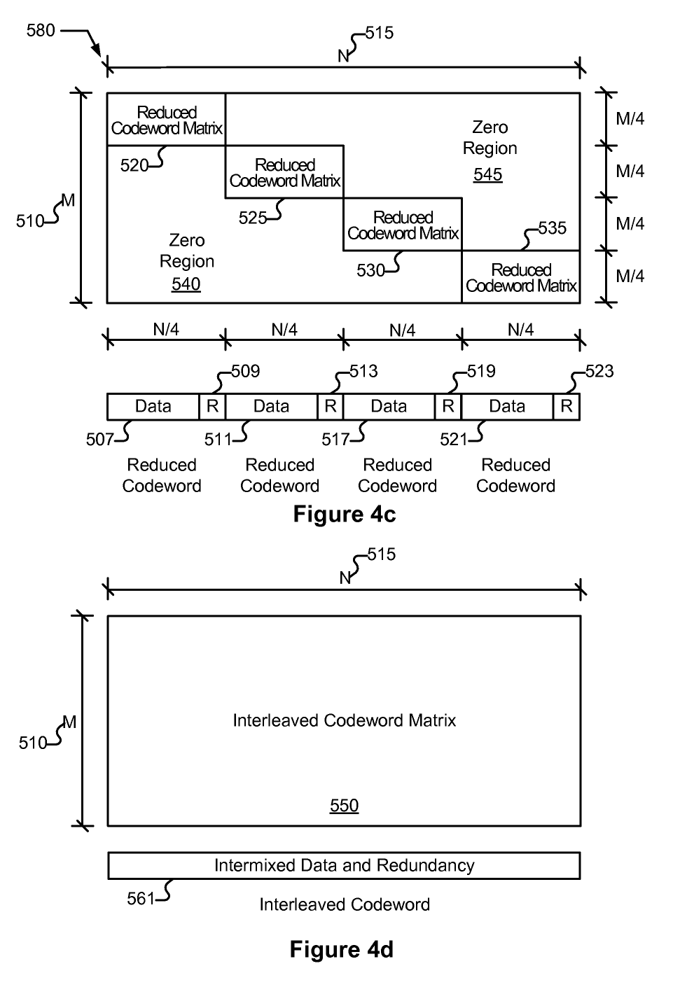

Turning to FIG. 4, another example of generating reduced codewords, and an interleaved codeword corresponding to desired codeword matrix where n equals two is shown. Turning to FIG. 4a, a standard LDPC codeword including data 501 and redundancy 503 is represented as desired codeword matrix 505. Desired codeword matrix 505 is comprised of a number (M) of rows 510 and a number (N) of columns 515. The number of columns 515 defines the LDPC code length, and the number of rows 510 represent the number of parity check equations used in the LDPC code. Each column of desired codeword matrix 505 includes a number of logic ‘1’s and a number of logic ‘0’s, and the number of logic ‘1’s is generally referred to as a column weight (Wc). Similarly, each row of desired codeword matrix 505 includes a number of logic ‘1’s and a number of logic ‘0’s, and the number of logic ‘1’s is generally referred to as a row weight (Wr).

Turning to FIG. 4b, four reduced codewords are designed to each be one quarter the size (i.e., n=2) of the above mentioned standard codeword. The first reduced codeword includes data 507 and redundancy 509, the second reduced codeword includes data 511 and redundancy 513, the third reduced codeword includes data 517 and redundancy 519, and the fourth reduced codeword includes data 521 and redundancy 523. The first reduced codeword is represented by a reduced codeword matrix 520, the second reduced codeword is represented by a reduced codeword matrix 525, the third reduced codeword is represented by a reduced codeword matrix 530, and the fourth codeword is represented by a reduced codeword matrix 535. In this case, each of reduced codeword matrices 520, 525, 530, 535 includes one quarter of the rows (M/4) and one quarter of the columns (N/4) of that included in desired codeword matrix 505. Reduced codeword matrix 520 is derived from the columns 0 through (N/4)−1 and the rows 0 through (M/4)−1 of desired codeword matrix 505. Reduced codeword matrix 525 is derived from columns N/4 through (N/2)−1 and rows N/4 through (N/2)−1 of desired codeword matrix 505. Reduced codeword matrix 530 is derived from columns N/2 through (3N/4)−1 and rows M/2 through (3M/4)−1 of desired codeword matrix 505. Reduced codeword matrix 535 is derived from columns 3N/4 through N and rows 3M/4 through M of desired codeword matrix 505.

The column weight of each of columns 0 through (N/4)−1 of reduced codeword matrix 520 is the same as the corresponding columns of desired codeword matrix 505. Thus, whatever logic ‘1’s are distributed across rows 0 through (N/4)−1 and columns 0 through (M/4)−1 are incorporated into reduced codeword matrix 520. The column weight of each of columns N/4 through (N/2)−1 (column N/4 corresponds to the first column of reduced codeword matrix 525, and column (N/2)−1 corresponds to the last column of reduced codeword matrix 525) of reduced codeword matrix 525 is the same as the corresponding columns of desired codeword matrix 505. The column weight of each of columns N/2 through (3N/4)−1 (column N/2 corresponds to the first column of reduced codeword matrix 530, and column (3N/4)−1 corresponds to the last column of reduced codeword matrix 530) of reduced codeword matrix 530 is the same as the corresponding columns of desired codeword matrix 505. The column weight of each of columns 3N/4 through N (column 3N/4 corresponds to the first column of reduced codeword matrix 535, and column N corresponds to the last column of reduced codeword matrix 535) of reduced codeword matrix 535 is the same as the corresponding columns of desired codeword matrix 505.

As shown in FIG. 4c and FIG. 4d, the four reduced codeword matrices 520, 525, 530, 535 may be used to generate a full size codeword matrix 550. In particular, as shown in FIG. 4c, a zero region 540 and a zero region 545 are assumed for all areas not covered by one of codeword matrices 520, 525, 530, 535. By including zero regions 540, 545, an overall matrix 580 is defined that exhibits the same number of columns and rows as included in desired codeword matrix 505. Zero regions 540, 545 may then be interleaved with reduced matrices 520, 525, 530, 535. This interleaving process may be performed on a column by column basis. In some embodiments of the present invention, the interleaving is random. This process of interleaving is carried out until all columns of matrix 580 have been included in interleaved codeword matrix 550. Based on the disclosure provided herein, one of ordinary skill in the art will recognize a myriad of interleaving schemes and approaches that may be applied to matrix 580 to achieve a desirable interleaved codeword matrix 550. Further, based on the disclosure provided herein, one of ordinary skill in the art will recognize other reduced codeword matrix sizes that may be used in accordance with various embodiments of the present invention. In any event, the aforementioned four reduced codeword matrices are interleaved together to create an interleaved codeword 561. Interleaved codeword 561 includes data 507, 511, 517, 521 and redundancy 509, 513, 519, 523 randomly or pseudo-randomly intermixed.

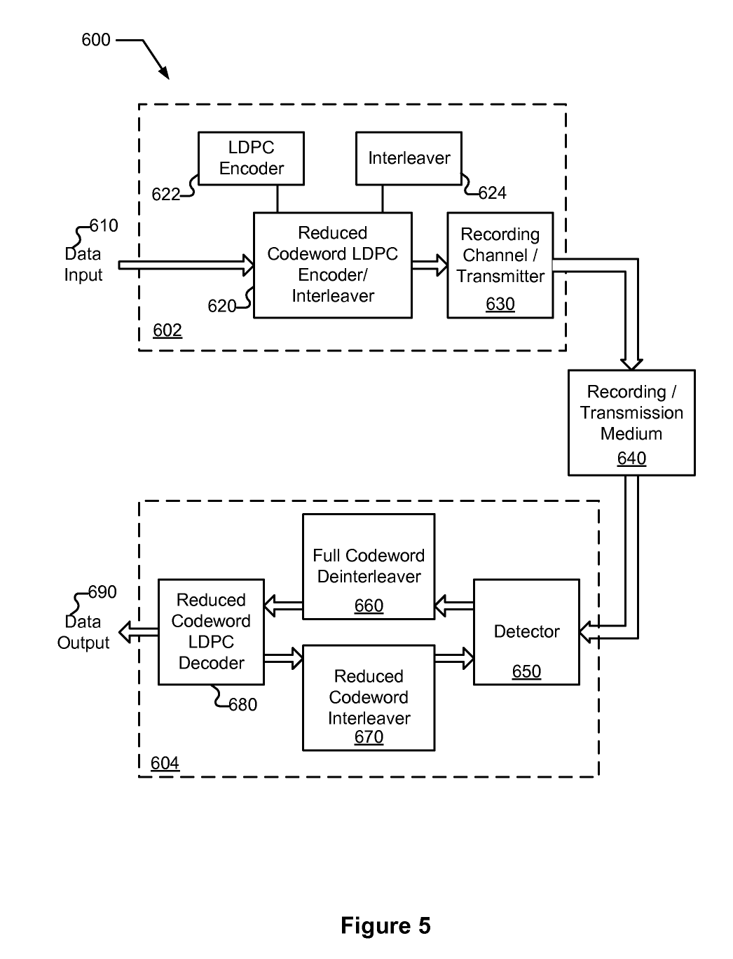

Turning to FIG. 5, a data transfer system 600 utilizing a reduced codeword in accordance with one or more embodiments of the present invention is depicted. Data transfer system 600 includes an encoding portion 602 (shown in dashed lines), a decoding portion 604 (shown in dashed lines) and a data transfer medium 640. Encoding portion 602 receives a data input, encodes the data input, and transfers the encoded data input via data transfer medium 640. Decoding portion 604 receives encoded data from data transfer medium 640, decodes the information, and provides a data output 690. Each of encoding portion 602 and decoding portion 604 operate on reduced codewords and are not designed to process a non-reduced codeword size (e.g., it is designed to handle a matrix of the size of reduced codeword matrix 425, but not to handle a matrix the size of interleaved codeword matrix 450). It should be noted that data transfer system 600 may be implemented in relation to a number of different systems. For example, data transfer system 600 may be implemented in a hard disk drive system or a cellular communication system. Where data transfer system 600 is implemented in a hard disk drive system, recording channel/transmitter 630 may be a read head and data transfer channel 640 may include a magnetic storage medium. In contrast, where data transfer system 600 is implemented in a cellular communication system, recording channel/transmitter 630 may be a cellular telephone transmitter and data transfer channel 640 may include the air through which the transmission is effected. Based on the disclosure provided herein, one of ordinary skill in the art will recognize a variety of systems in which data transfer system 600 may be utilized.

Encoding portion 602 includes a reduced codeword LDPC encoder/interleaver 620 and a recording channel/transmitter 630. Reduced codeword LDPC encoder/interleaver 620 performs at least two functions. The first function is that of LDPC encoding of a data input that is performed by an LDPC encoder 622. LDPC encoder 622 is designed to encode a data input 610 into a set of reduced codewords such as those described in relation to FIG. 3b and FIG. 4b above. Thus, where the set of reduced codeword includes two “half” size matrices, LDPC encoder 622 is designed to work on a “half” size matrix. As a smaller matrix reduces the complexity of LDPC encoder 622, this reduction in matrix size is desirable. In particular, the encoding process requires operation on a longer codeword in a given pass. Thus, by reducing the size of the rows, the complexity of LDPC encoder 622 may be substantially reduced. LDPC encoder 622 may be designed using encoder design techniques that are well known in the art. In contrast to existing LDPC encoders, LDPC encoder 622 is designed to produce two “half” size codewords (e.g., reduced codewords corresponding to reduced codeword matrix 425 and reduced codeword matrix 430) that together represent a desired codeword, rather than a single full size codeword. It should be noted that the foregoing is merely exemplary and that other sizes of reduced codewords may be produced by encoder 622. For example, a “quarter” size codeword, or a “fifth” size codeword may be produced. In such a case, LDPC encoder 622 is designed to work on a “quarter” or “fifth” size matrix such as that discussed above in relation to FIG. 4b. Again, use of a smaller codeword is desirable because it reduces the encoder complexity. In such a case, LDPC encoder 622 may be designed using encoder design techniques that are well known in the art. LDPC encoder 622 is, however, designed to produce four “quarter” size or “fifth” size codewords (e.g., reduced codeword matrix 520, reduced codeword matrix 525, reduced codeword matrix 530 and reduced codeword matrix 535) that together represent a desired codeword, rather than a single full size codeword. Based on the disclosure provided herein, one of ordinary skill in the art will recognize a variety of other reduced codeword sizes and corresponding LDPC encoder designs that may be used in accordance with different embodiments of the present invention.

The second function of reduced codeword LDPC encoder/interleaver 620 is that of interleaving the reduced codeword matrices to produce an interleaved codeword. This process is accomplished using an interleaver 624 and is exemplified by the transformation of the reduced codewords of FIG. 3b into the interleaved codeword of FIG. 3d. Similarly, the process is exemplified by the transformation of the reduced codewords of FIG. 4b into the interleaved codeword of FIG. 4d. Such interleaving may be done using any interleaver that is capable of interleaving, for example, on a column by column basis. In some cases, it is desirable to design an interleaver that operates to randomly intermix the columns of the reduced codeword matrices produced by LDPC encoder 622.

The interleaved codeword produced by reduced codeword LDPC encoder/interleaver 620 is provided to recording channel/transmitter 630. In turn, recording channel/transmitter 630 provides the encoded data to a destination via data transfer medium 640. As discussed above, data transfer medium 640 may include, but is not limited to, a storage medium or a wireless transfer medium. It should be noted that the interleaved codeword transferred via data transfer medium is the same interleaved codeword referred to as being received by decoding portion 604. One of ordinary skill in the art will recognize that while the same interleaved codeword is referred to, that the received interleaved codeword may be different from that of the transmitted one as noise and other error sources often cause various changes in the received interleaved codeword compared to the transmitted interleaved codeword. Thus, when an interleaved codeword is referred to herein including in the claims and the same interleaved codeword is referred to as being decoded, it is understood that one or more errors may have been introduced into the received interleaved codeword.

Data is received from data transfer medium 640 by decoding portion 604. Where, for example, data transfer medium 640 is a storage medium, decoding portion 604 may be associated with a read head assembly. As another example, where data transfer medium 640 is a wireless communication medium, decoding portion 604 may be associated with a receiver. Decoding portion 604 includes a detector 650 that is operable to detect the originally transferred data. Detector 650 may be any circuit or system that is capable of receiving data from data transfer medium 640 and detecting the original data therein. Thus, detector 650 may be, but is not limited to, a soft output Viterbi (SOVA) detector or a maximum a posteriori probability (MAP) detector as are known in the art.

Detector 650 provides an output to a full codeword de-interleaver 660. Full codeword de-interleaver 660 applies substantially the reverse process as that originally applied to the transferred data by interleaver 624. De-interleaving the detected data causes a transformation from the interleaved codeword back to the reduced codewords that were originally encoded by LDPC encoder 622. As an example, the de-interleaving process causes a transformation from interleaved codeword 421 to the reduced codewords of FIG. 3c. As another example, the de-interleaving process causes a transformation from interleaved codeword matrix 561 to the reduced codewords of FIG. 4c. Based on the disclosure provided herein, one of ordinary skill in the art will recognize a variety of sizes for reduced codewords that may be used in relation with different embodiments of the present invention. Further based on the disclosure provided herein, one of ordinary skill in the art will recognize a variety of interleaving and de-interleaving approaches that may be applied by interleaver 622 and de-interleaver 660 in accordance with different embodiments of the present invention.

The de-interleaved data is passed from full codeword de-interleaver 660 to a reduced codeword LDPC decoder 680. Reduced codeword LDPC decoder 680 performs LDPC decoding on each of the reduced codewords that are received from full codeword de-interleaver 660. The decoding performed may be any LDPC decoding known in the art. As an example, where two “half” size reduced codeword matrices are utilized, reduced codeword LDPC decoder 680 may perform decoding on the reduced codeword including data 411 and redundancy 413, and subsequently on the reduced codeword including data 417 and redundancy 419 of FIG. 3b. Of note, the design of reduced LDPC decoder 680 may be greatly reduced when it is designed to operate on a reduced codeword size, and not on codewords of a larger size. As another example, where four “quarter” size reduced codeword matrices are utilized, reduced codeword LDPC decoder 680 may perform decoding on the reduced codeword including data 507 and redundancy 509, then on the reduced codeword including data 511 and redundancy 513, then on the reduced codeword including data 517 and redundancy 519, and then on the reduced codeword including data 521 and redundancy 523 of FIG. 4b. Again, based on the disclosure provided herein, one of ordinary skill in the art will recognize a variety of sizes for reduced codewords that may be used in relation with different embodiments of the present invention. As a smaller codeword reduces the complexity of LDPC decoder 680, this reduction in matrix size is desirable. In particular, the decoding process requires operation on a larger matrix row in a given pass. Thus, by reducing the size of the codeword, the complexity of the utilized LDPC decoder may be substantially reduced.

Where the decoding process does not provide a satisfactory result (i.e., a result converging on the original data input 610), the process of detecting, interleaving and decoding may be iteratively repeated to increase the confidence in any result. In such a case, the output of reduced codeword LDPC decoder 680 is provided to a reduced codeword interleaver 670 that re-interleaves the reduced codewords. Similar to the process performed by interleaver 624, reduced codeword interleaver 670 is exemplified by the transformation of the reduced codewords of FIG. 3b into the interleaved codeword of FIG. 3d. Similarly, the process is exemplified by the transformation of the reduced codeword of FIG. 4b into the interleaved codeword of FIG. 4d.

The re-interleaved data is provided from reduced codeword interleaver 670 to detector 650. In turn, detector 650 performs its detection processes and again provides an output to full codeword de-interleaver 660. The decoding process continues until the decoded output converges either to a satisfactory point, or in some cases until it is determined that a convergence is not possible as is known in the art. Ultimately, a data output 690 corresponding to data input 610 is provided by reduced codeword LDPC decoder 680.

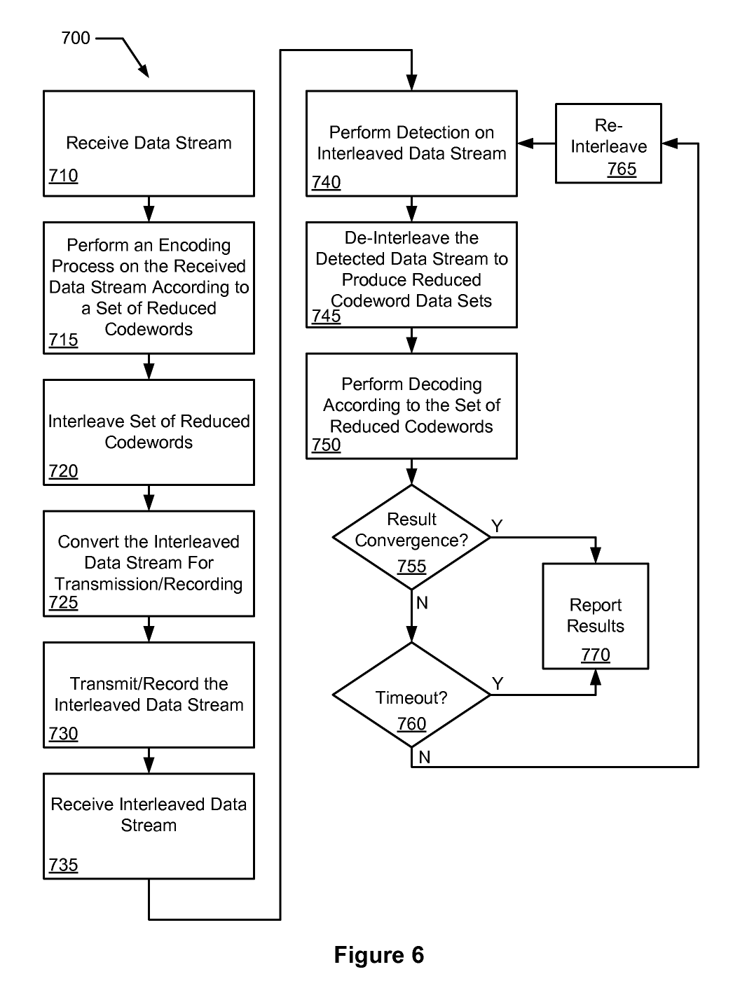

Turning to FIG. 6, a flow diagram 700 depicts a process in accordance with one or more embodiments of the present invention for data processing using reduced codewords. Following flow diagram 700, a data stream is received (block 710). This data stream may be, for example, a series of binary values that are intended to be transferred. The transfer may include, for example, storing the data to a storage medium or transferring the data wirelessly to a receiving device. In some cases, the received data my have been previously interleaved (e.g., shuffled) to increase the data randomness and thereby increase the robustness of any transfer. In such cases, another interleaver would be in place between data input 610 and reduced codeword LDPC encoder/interleaver 620. Further, in such cases, a corresponding de-interleaver may be included between reduced codeword LDPC decoder 680 and data output 690.

The received data stream is encoded in accordance with a set of reduced codewords (block 715). The result of the encoding process is a number of reduced codewords such as those exemplified by FIG. 3b and FIG. 4b. The reduced codewords are then interleaved to create an interleaved codeword such as that exemplified by FIG. 3d and FIG. 4d (block 720). The interleaved data is then converted for transmission or decoding depending upon the system in which the process is implemented (block 725). This may include, for example, performing a digital to analog conversion and providing the converted data to a transmitter or read channel. The converted data is then transferred (block 730). Again, this transfer may include, but is not limited to, a storage operation or a wireless transmission operation. Based on the disclosure provided herein, one of ordinary skill in the art will recognize a variety of systems in which the process of flow diagram 700 may be applied, and appropriate processes for preparing the interleaved data for transfer in accord with those systems.

The transferred information is received by a receiving device (block 735), and detection is performed on the previously encoded and interleaved data (block 740). In particular, a detection process is performed to detect the interleaved codeword that was transferred. This may include, but is not limited to, either application of a SOVA detector or a MAP detector as are known in the art. The detected data is then de-interleaved using a process that is substantially the inverse of the interleaving that was done is block 720 (block 745). The result of the de-interleaving process is the reduced codewords that were originally encoded. An LDPC decoding process is then performed on the reduced codewords (block 750) to recover the original data stream. Such LDPC decoding may be done using LDPC decoding techniques that are known in the art. A discussion of exemplary LPDC decoding techniques are more fully discussed in U.S. patent application Ser. No. 11/756,736 entitled “SYSTEMS AND METHODS FOR LDPC DECODING WITH POST PROCESSING”, and filed by Zhong on Jun. 1, 2007. The entirety of the aforementioned reference is incorporated herein by reference for all purposes. While the LDPC decoding process and the utilized LDPC decoder may be known in the prior art, the LDPC decoder is tailored to decode data of the magnitude of the reduced codeword matrix. As the reduced codeword matrices are substantially smaller than the size of a traditional matrix (e.g., desired codeword matrix 405 of FIG. 3a), the complexity of the LDPC decoder is greatly reduced. Such a reduction in decoder complexity renders LDPC decoding less costly and more practical.

It is then determined if the result provided by the decoder has converged (block 755). As is known in the art, convergence typically occurs where the result provided by the decoder represents the original data input. Where the result has not yet converged (block 755), it is determined whether a timeout or some other error indication has occurred that suggests that a result may not be achieved (block 760). This occurs where, for example, too much noise is introduced to the transferred data and recovering the data is rendered impossible. Where the timeout has not occurred (block 760), the data from the decoder is re-interleaved (block 765) and the interleaved data is returned to the detector (block 740) where the decoding process is iteratively repeated. Alternatively, where either the output of the decoder has converged (block 755) or a timeout has occurred (block 760), the decoder results are provided as an output.

One or more embodiments of the present invention provide for iterative signal detection and decoding for magnetic recording channel which provides very good signal to noise ratio (SNR) gain at low hardware cost. Such embodiments may utilize a MAP detector, iteratively working with an LDPC decoder to effectively recover the read back signals corrupted by both random and burst errors. To ensure high error correction capability, the code length of the LDPC code may be chosen to be equivalent to the sector size of hard disk drive (HDD). This code length may be substantially reduced by designing an inter-codeword interleaved code based on reduced codeword matrices. The code used may be a Quasi Cyclic LDPC code that features simple hardware-saving encoder and decoder architecture. The system operates on a reduced codeword matrix, on a codeword-by codeword basis. Use of such a reduced codeword matrix reduces the hardware complexity and size, while maintaining reasonable performance. The system includes a interleaver/deinterleaver set that works on an m-codeword base. In particular, the interleaver interleaves the encoded data bits in codewords cwkm+1, cwkm+2, . . . , cw (k+1)m, where k is the index of block of codewords. One such block consists of m codewords. Therefore, buffers to store these codewords are used. However, since the codeword size (i.e., the size of the reduced codeword matrix) is 1/m of the corresponding full size matrix, the buffer size on the encoder side is the same as would be required where a reduction in codeword size was not employed.

It should be noted that the number of reduced codewords that are to be interleaved together may be a power of two, or may be any arbitrary integer depending upon the particular design. The reduced codewords imply a smaller LDPC decoder that is less complex and/or requires a reduced area. The parity check matrix of the interleaved codeword is obtained by interleaving small matrices corresponding to the reduced codewords as illustrated in FIG. 3 and FIG. 4 above. Generally speaking, for same type of LDPC codes, the larger the codeword length, the better the error correction performance and the higher the complexity. Thus, some embodiments of the present invention achieve the performance of larger LDPC code using a lower complexity LDPC decoder designed to handle a reduced size codeword.

In conclusion, the invention provides novel systems, devices, methods and arrangements for processing information. While detailed descriptions of one or more embodiments of the invention have been given above, various alternatives, modifications, and equivalents will be apparent to those skilled in the art without varying from the spirit of the invention. For example, one or more embodiments of the present invention may be applied to various data storage systems and digital communication systems, such as, for example, tape recording systems, optical disk drives, wireless systems, and digital subscribe line systems. Therefore, the above description should not be taken as limiting the scope of the invention, which is defined by the appended claims.

What is claimed is:

1. A decoding system, wherein the decoding system comprises:
a de-interleaver, wherein the de-interleaver is operable to receive an interleaved codeword, wherein the interleaved codeword includes two or more reduced codewords that are interleaved together, and wherein the de-interleaver is operable to provide a representation of the two or more reduced codewords; and
a decoder, wherein the decoder is operable to decode the two or more reduced codewords.

2. The decoding system of claim 1, wherein the decoder is an LDPC decoder.

3. The decoding system of claim 2, wherein the complexity of the LDPC decoder is tailored to the size of one of the two or more reduced codewords.

4. The decoding system of claim 3, wherein the complexity of the LDPC decoder renders it unable to decode a codeword of a length of the interleaved codeword.

5. The decoding system of claim 1, wherein each of the two or more reduced codewords corresponds to a respective reduced codeword matrix, wherein the interleaved codeword corresponds to an interleaved codeword matrix, and wherein the column weight of each reduced codeword matrix is the same as the column weight of corresponding columns of the interleaved codeword matrix.

6. The decoding system of claim 5, wherein the interleaved codeword matrix includes a first number of columns and a first number of rows, wherein at least one of the respective codeword matrices includes a second number of columns and a second number of rows, wherein the second number of columns is less than the first number of columns, and wherein the second number of rows is less than the first number of rows.

7. The decoding system of claim 5, wherein the interleaved codeword matrix includes a first number of columns and a first number of rows, wherein at least one of the respective codeword matrices includes a second number of columns and a second number of rows, wherein the second number of columns is less than the first number of columns, wherein the second number of rows is less than the first number of rows, and wherein the second number of columns is the first number of columns divided by an integer value, and wherein the second number of rows is the first number of rows divided by the integer value.

8. The decoding system of claim 5, wherein the interleaved codeword matrix includes a first number of columns and a first number of rows, wherein at least one of the two or more reduced codeword matrices includes a second number of columns and a second number of rows, wherein the second number of columns is less than the first number of columns, wherein the second number of rows is less than the first number of rows, and wherein the second number of columns is the first number of columns divided by a power of two, and wherein the second number of rows is the first number of rows divided by the power of two.

9. The decoding system of claim 1, wherein the interleaved codeword matrix includes the two or more reduced codeword matrices interleaved together on a column by column basis.

10. The decoding system of claim 9, wherein the column by column interleaving is selected from a group consisting of: random interleaving, pseudo-random interleaving, non-random interleaving.

11. The decoding system of claim 1, wherein the total number of the two or more reduced codeword matrices is the power of two.

12. The decoding system of claim 1, wherein the decoding system further includes an encoder and an interleaver, wherein the encoder is operable to add a first parity to a first data set and to add a second parity to a second data set, and wherein the interleaver is operable to interleave the first data set including the first parity with the second data set including the second parity to create the interleaved codeword.

13. A data transfer system, wherein the data transfer system comprises:
an encoder, wherein the encoder is operable to receive an input data set and to provide at least a first reduced codeword and a second reduced codeword, wherein the first reduced codeword represents a first portion of the input data set augmented with a first parity, and wherein the second reduced codeword represents a second portion of the input data set augmented with a second parity;
an interleaver, wherein the interleaver is operable to interleave at least the first reduced codeword and the second reduced codeword to create an interleaved coderword,
a data transfer medium, wherein the data transfer medium transfers the interleaved codeword as a second interleaved codeword, and wherein the second interleaved codeword corresponds to the first interleaved codeword with introduced noise;
a de-interleaver, wherein the de-interleaver is operable to receive the second interleaved codeword, and wherein the de-interleaver is operable to provide a representation of the first reduced codeword and the second reduced codeword; and
a decoder, wherein the decoder is operable to decode an input of a size consistent with the first reduced codeword and the second reduced codeword.

14. The data transfer system of claim 13, wherein the first reduced codeword corresponds to a first reduced codeword matrix, wherein the second reduced codeword corresponds to a second reduced codeword matrix, and wherein the interleaved codeword corresponds to an interleaved codeword matrix.

15. The data transfer system of claim 14, wherein the column weight of each column of the first reduced codeword matrix and the second reduced codeword matrix is the same as the column weight of corresponding columns of the interleaved codeword matrix.

16. The data transfer system of claim 13, wherein the encoder is and LDPC encoder, and wherein the decoder is an LDPC decoder.

17. The data transfer system of claim 16, wherein the complexity of the LDPC decoder is tailored to the size of one of the first reduced codeword matrix or the second reduced codeword matrix.

18. The data transfer system of claim 13, wherein the total number of reduced codewords including the first reduced codeword and the second reduced codeword that are interleaved to create the interleaved codeword is a power of two.

19. A method for reduced complexity data processing, the method comprising:
receiving an interleaved codeword, wherein the interleaved codeword is generated by interleaving two or more reduced codewords, wherein each of the two or more interleaved codewords includes a combination of data and parity;
de-interleaving the interleaved codeword to yield the two or more reduced codewords; and
decoding each of the two or more reduced codewords, wherein the respective data of each of the two or more reduced codewords is recovered.

20. The method of claim 19, the method further comprising:
receiving an input data set;
encoding a first portion of the input data set to yield a first one of the two or more reduced codewords;
encoding a second portion of the input data set to yield a second one of the two or more reduced codewords; and
interleaving the two or more reduced codeword matrices to create the interleaved codeword.
